(19) United States
(12) Patent Application Publication
(10) Pub. No.: US 2026/0121582 A1
(43) Pub. Date: Apr. 30, 2026

(54) ANALOG FILTER CIRCUIT AND COMMUNICATION DEVICE INCLUDING THE SAME

(71) Applicant: Samsung Electronics Co., Ltd., Suwon-si (KR)

(72) Inventors: Sangsung LEE, Suwon-si (KR); Jonghyun KIM, Suwon-si (KR); Seongho PARK, Suwon-si (KR); Sangmin YOO, Suwon-si (KR); Jongsoo LEE, Suwon-si (KR)

(73) Assignee: Samsung Electronics Co., Ltd., Suwon-si (KR)

(21) Appl. No.: 19/003,269

(22) Filed: Dec. 27, 2024

(30) Foreign Application Priority Data
Dec. 29, 2023 (KR) 10-2023-0196956
May 20, 2024 (KR) 10-2024-0065103

(51) Int. Cl. H03F 1/02; H03F 3/24; H03H 7/06; H03H 11/04; H04B 1/04

(52) U.S. Cl. CPC H03F 1/0205; H03F 3/245; H03H 7/06; H03H 11/04; H04B 1/0475; H03F 2200/451; H04B 2001/045

(57) ABSTRACT

An analog filter circuit includes an active filter configured to filter a transmission signal, the active filter including an active element to which a power supply voltage is applied, and a passive filter connected to an output terminal of the active filter, the passive filter including a passive element having a dynamically variable impedance.

### CROSS-REFERENCE TO RELATED APPLICATION

This application claims priority to and the benefits of Korean Patent Application No. 10-2023-0196956 filed at the Korean Intellectual Property Office on Dec. 29, 2023 and Korean Patent Application No. 10-2024-0065103 filed at the Korean Intellectual Property Office on May 20, 2024, the entire contents of each of which are incorporated herein by reference in their entireties.

### BACKGROUND

### (a) Field

The disclosure relates to an analog filter circuit and a communication device including the same.

### (b) Description of Related Art

In communication systems, the demand for lower power consumption devices is increasing. Since a transmitter is a component within a terminal that consumes a substantial portion of the terminal's overall power, reducing the transmitter's power consumption would reduce the terminal's total power usage. The power consumption of the transmitter may be reduced by reducing the current consumption in the RF front end, when the output power of the transmitter is relatively high.

### SUMMARY

The present disclosure is to provide an analog filter circuit and a communication device including the analog filter circuit for reducing power consumption of a transmitter when the output power of the transmitter is relatively low.

Embodiments provide an analog filter circuit for improving power efficiency of a transmitter and a communication device including the transmitter.

An analog filter circuit according to embodiments includes an active filter configured to filter a transmission signal, the active filter including an active element to which a power supply voltage is applied, and a passive filter connected to an output terminal of the active filter, the passive filter including a passive element having a dynamically variable impedance.

According to embodiments, a transmitter includes a baseband filter having a dynamically variable internal impedance, the baseband filter being configured to filter a baseband signal to obtain a first transmission signal, a mixer configured to up-convert a frequency of the first transmission signal based on an oscillation signal to obtain a second transmission signal, a driving amplifier configured to amplify the second transmission signal to generate a radio frequency (RF) input signal, and a power amplifier configured to amplify the RF input signal to generate an RF output signal.

A communication device according to embodiments includes a power modulator configured to generate a power supply voltage of a first level or a second level, the second level being lower than the first level, and a transmitter including a baseband filter configured to filter a baseband signal to obtain a filtered baseband signal, the baseband filter having a variable internal impedance, a mixer configured to up-convert a frequency of the filtered baseband signal to generate a first transmission signal, a drive amplifier configured to amplify the first transmission signal to generate an RF input signal, and a power amplifier configured to amplify the RF input signal using the power supply voltage to generate an RF output signal.

### BRIEF DESCRIPTION OF THE DRAWINGS

FIG. 1 is a block diagram schematically illustrating a transmitter according to embodiments.

FIG. 2 is a graph showing the current consumption and operating frequency of a transmitter according to the transmitter output power according to embodiments.

FIG. 3 is a block diagram illustrating a communication device according to embodiments.

FIG. 4 is a schematic diagram of an equivalent circuit of an analog filter according to embodiments.

FIG. 5 is a flowchart of an operation method of a communication device according to embodiments.

FIG. 6 is a block diagram illustrating a transmitter according to embodiments.

FIG. 7 is a flowchart of a method of operating a communication device according to embodiments.

FIGS. 8 and 9 are block diagrams showing examples of transmitters controlled by the method of FIG. 7.

FIG. 10 is a block diagram showing an analog filter of the transmitter of FIG. 8.

FIG. 11 is a flowchart of an operation method of a communication device according to embodiments.

FIGS. 12 and 13 are block diagrams showing examples of driving amplifier blocks controlled by the method of FIG. 11.

FIG. 14 is a block diagram illustrating a portion of a communication device according to embodiments.

FIG. 15 is a flowchart of an operation method of a communication device according to embodiments.

FIG. 16 is a block diagram illustrating a communication device according to embodiments.

FIG. 17 is a block diagram illustrating a mobile terminal to which a communication device according to embodiments is applied.

### DETAILED DESCRIPTION

In the following detailed description, only certain examples of the inventive concepts have been shown and described, simply by way of illustration. As those skilled in the art would realize, the described examples may be modified in various different ways, all without departing from the spirit or scope of the inventive concepts.

Accordingly, the drawings and description are to be regarded as illustrative in nature and not restrictive. Like reference numerals designate like elements throughout the specification. In the flowchart described with reference to the drawings, the order of operations may be changed, several operations may be merged, some operations may be split, and certain operations may not be performed.

Additionally, expressions written in the singular may be interpreted as singular or plural, unless explicit expressions such as “one” or “singular” are used. Terms that include ordinal numbers, such as first, second, etc., may be used to describe various components, but the components are not limited by these terms. These terms may be used to distinguish one component from another.

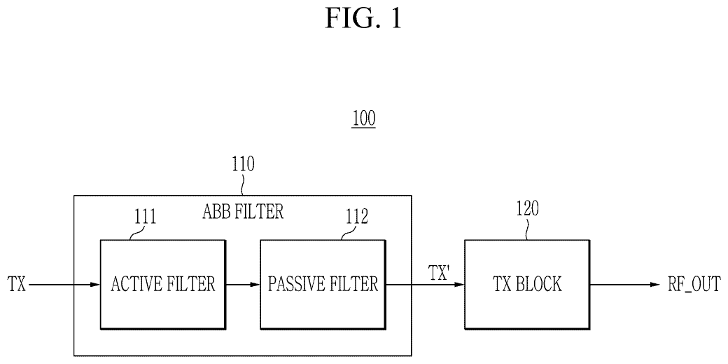

FIG. 1 is a block diagram schematically illustrating a transmitter according to embodiments.

Referring to FIG. 1, a transmitter 100 may receive a transmission signal TX which is an analog signal, process the transmission signal TX, and output an RF output signal RF_OUT. The transmitter 100 may include an analog filter 110 and/or a TX block 120.

The analog filter 110 may filter a transmission signal TX to remove unwanted images, nonlinear components, noise, etc. caused by a previous digital-to-analog conversion. The analog filter 110 may demodulate a transmission signal TX to baseband. The analog filter 110 may include an analog baseband (ABB) filter. In embodiments, the analog filter 110 may be used for a wireless transceiver that supports various bandwidth wireless communication technologies, such as, for example, New Radio (NR), Global System for Mobile communications (GSM), Enhanced Data GSM Environment (EDGE), High Speed Packet Access (HSPA), Wideband Code Division Multiple Access (WCDMA), Long Term Evolution (LTE) 1.4M, LTE 3M, LTE 5M, LTE 10M, LTE 15M, LTE 20M, etc.

The analog filter 110 may include an active filter 111 and/or a passive filter 112. The active filter 111 may include active components such as transistors and amplifiers (e.g., a baseband variable-gain amplifier (VGA)), and the passive filter 112 may include passive components such as resistors, capacitors, and/or inductors. Power supply voltage is applied to the active element of the active filter 111, and current consumption may occur in the active filter 111. In embodiments, the impedance of the passive filter 112 may be changed. The passive filter 112 may have a larger impedance in a region where the output power of the transmitter 100 is relatively low than in a region where the output power of the transmitter 100 is relatively high. An output impedance of the active filter 111 may be increased by the larger impedance of the passive filter 112. A gain of the active filter 111 may be related to an output current of the active filter 111 and the output impedance of the active filter 111. For example, a higher output current of the active filter 111 may result in a higher gain of the active filter 111, and a higher output impedance of the active filter 111 may result in a higher gain of the active filter 111. Therefore, when the output impedance of the active filter 111 increases, the gain of the active filter 111 may be substantially maintained even if the output current of the active filter 111 decreases.

In embodiments, the passive filter 112 may include only the load of the active filter 111. In embodiments, the passive filter 112 may include the load of the active filter 111 and the input impedance of the TX block 120. In embodiments, the passive filter 112 may include only the input impedance of the TX block 120.

The TX block 120 may receive an amplified transmission signal TX′ from the analog filter 110, process the transmission signal TX′, and output an RF output signal RF_OUT. The TX block 120 may include a mixer configured to mix a filtered transmission signal TX′, a drive amplifier DA configured to amplify an RF signal, a power amplifier PA configured to amplify an RF signal amplified from the DA, etc. In embodiments, the PA may not be in the TX block 120. The TX block 120 may up-convert a baseband signal TX′ provided from an analog filter 110 into an RF band signal, amplify the RF band signal, and output an RF output signal RF_OUT.

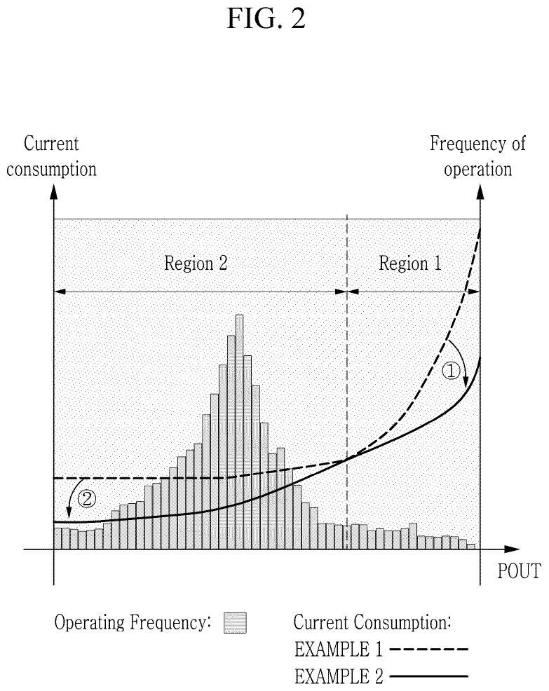

FIG. 2 is a graph showing the current consumption and operating frequency of a transmitter according to the output power of the transmitter according to embodiments.

Referring to FIGS. 1 and 2, the operating frequency (e.g., usage rate) of the transmitter 100 may be relatively low in Region 1 where the output power of the transmitter 100 is relatively high. The operating frequency of the transmitter 100 may be relatively high in Region 2 where the output power of the transmitter 100 is relatively low. For example, the maximum (or highest) value of the operating frequency of the transmitter 100 may be included in Region 2. The current consumption due to the higher output power of the transmitter 100 in Region 1 and Region 2 may be expressed as in EXAMPLE 1. By reducing the gain of the TX block 120 in FIG. 1, the current consumption may be reduced, as in the second example EXAMPLE 2 in Region 1(\textcircled{1}). However, since the transmitter 100 has a higher frequency of operation, that is, a higher number of operational occurrences, in Region 2, to minimize (or reduce) the current consumption of the transmitter 100, the current consumption in Region 2 is reduced, as in the second example EXAMPLE 2(\textcircled{2}). According to embodiments, Region 2 may refer to transmissions having a lower output power (e.g., an output power below a power threshold), and Region 1 may refer to transmissions having a higher output power (e.g., an output power above the power threshold).

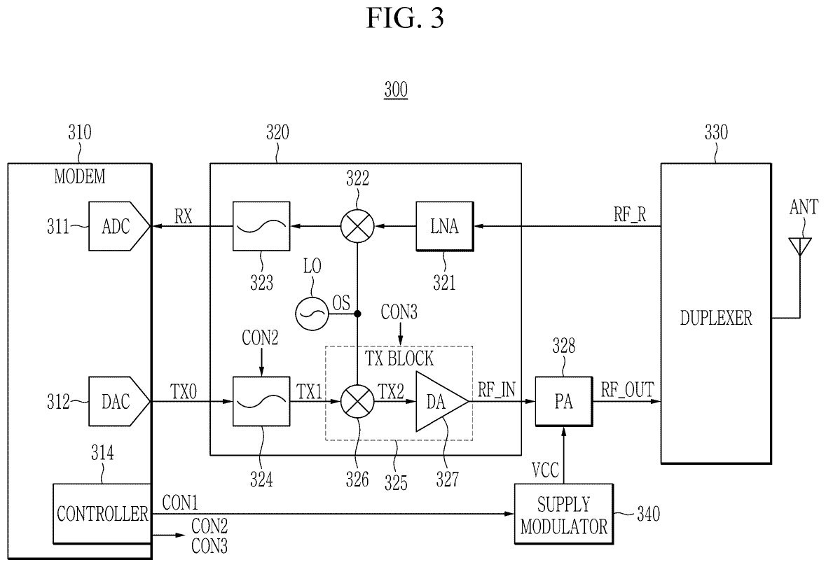

FIG. 3 is a block diagram illustrating a communication device according to embodiments.

Referring to FIG. 3, a communication device 300 may connect to a wireless communication system by transmitting and receiving signals through an antenna ANT. The wireless communication system to which the communication device 300 may connect may also be referred to as a Radio Access Technology (RAT), and may be a wireless communication system utilizing a cellular network such as a next-generation wireless system, a 5th generation (5G) wireless system, a Long Term Evolution (LTE) wireless system, an LTE-Advanced system, a Code Division Multiple Access (CDMA) wireless system, or a Global System for Mobile Communications (GSM) system. Alternatively, it may be a Wireless Local Area Network (WLAN) system or any other type of wireless communication system. In the following description, it will be assumed that the wireless communication system to which the communication device 300 connects is a wireless communication system utilizing a cellular network. It should be understood, however, that embodiments of the present disclosure are not limited thereto.

The wireless communication network of the wireless communication system may support communications by a plurality of wireless communication devices, including the communication device 300, through the sharing of available network resources. For example, in a wireless communication network, information may be transmitted through various multiple access schemes such as Code Division Multiple Access (CDMA), Frequency Division Multiple Access (FDMA), Time Division Multiple Access (TDMA), Orthogonal Frequency Division Multiple Access (OFDMA), Single Carrier Frequency Division Multiple Access (SC-FDMA), OFDM-FDMA, OFDM-TDMA, or OFDM-CDMA.

The communication device 300 may refer to any device that connects to a wireless communication system. As one example of the communication device 300, a base station (BS) may generally refer to a fixed station that communicates with user equipment and/or other base stations, and may exchange data and control information by communicating with such user equipment and/or other base stations. For example, a base station may be referred to as a Node B, an evolved Node B (eNB), a next generation Node B (gNB), a sector, a site, a Base Transceiver System (BTS), an Access Point (AP), a relay node, a Remote Radio Head (RRH), a Radio Unit (RU), a small cell, or other similar terms. Here, the term “base station” or “cell” may be interpreted as a comprehensive concept representing, for example, a portion of an area or a function covered by a Base Station Controller (BSC) in a CDMA system, a Node-B in a WCDMA system, or an eNB or sector site in an LTE system. The term may encompass various coverage areas or ranges, including, but not limited to, mega cells, macro cells, micro cells, pico cells, femto cells, relay nodes, RRHs, RUs, and small cells.

As one example of the communication device 300, a user equipment (UE) may refer to any device that may be fixed or mobile and is capable of transmitting and/or receiving data and/or control information by communicating with a base station. For example, the user equipment may be referred to as terminal equipment, a mobile station (MS), a mobile terminal (MT), a user terminal (UT), a subscriber station (SS), a wireless device, a handheld device, or the like. Here, it is assumed that the communication device 300 is a user equipment (UE), but it should be understood that embodiments of the present disclosure are not limited thereto.

The communication device 300 may include a modem 310, a transceiver 320, a switch/duplexer 330, an antenna ANT, and/or a power modulator 340.

The modem 310 may process a baseband signal TX0 containing information to be transmitted according to a predetermined (or alternatively, given) communication method. The modem 310 may process the received baseband signal RX according to a set communication method. For example, the modem 310 may process a signal to be transmitted or a signal to be received according to a communication method such as OFDM OFDMA, WCDMA, or HSPA. In addition, the modem 310 may process the baseband signal TX0 or RX according to various communication schemes, in other words, various schemes in which techniques for modulating or demodulating the amplitude and/or frequency of the baseband signal TX0 or RX are applied. The modem 310 may include an analog/digital converter ADC 311, a digital/analog converter DAC 312, and/or a switch controller 314.

The ADC 311 may convert the baseband signal RX into a digital signal and output the resulting digital signal. Information may be extracted from the output digital signal by performing digital processing, such as filtering, demodulation, and/or decoding.

The DAC 312 may convert a digital signal to be transmitted into an analog signal, a baseband signal TX0. The DAC 312 may generate and output the baseband signal TX0 by performing digital processing such as filtering, modulation, and/or encoding of the information.

The controller 314 may provide control signals to the transceiver 320 and the power modulator 340. For example, the controller 314 may provide a control signal CON1 to a power modulator 340 which provides a supply voltage VCC to the power amplifier PA 328. The power modulator 340 may select the level of the supply voltage VCC based on the control signal CON1. The control signal CON1 may include an envelope signal generated by detecting an envelope of the baseband signal TX0. The controller 314 may provide a control signal CON2, which controls the impedance of the baseband filter 324, to the baseband filter 324. The controller 314 may provide a control signal CON3, which controls the operation of the mixer 326, the DA 327, and/or the PA 328, to the TX block 325. According to embodiments, the controller 314 may generate the control signal CON1 and/or the control signal CON2 based on information about the signal to be transmitted (e.g., the communication method, the communication scheme, and/or other information such as a channel condition, a transmission distance, etc.). According to embodiments, the controller 314 may determine an output power of the signal to be transmitted (e.g., an output power of RF_OUT) based on the information about the signal to be transmitted.

The RX path may include a low noise amplifier LNA 321, a mixer 322, and/or a baseband filter 323. The LNA 321, the mixer 322, and/or the baseband filter 323 may be included within the transceiver 320. The RF signal RF_R received through the antenna ANT may be amplified by the LNA 321.

The mixer 322 may perform frequency down-conversion of the received signal RF_R from a high-frequency band (e.g. RF band) to a baseband frequency using an oscillation signal OS provided by the local oscillator LO.

The baseband signal output by the mixer 322 may be filtered by a baseband filter 323 before being converted into digital I or Q signals by the ADC 311 for digital signal processing.

The TX path may include a baseband filter 324, a mixer 326, a DA 327, and/or a PA 328. In embodiments, the PA 328 may be located external to the transceiver 320.

The baseband filter 324 may include a low pass filter. The baseband filter 324 may filter the baseband signal TX0 received from the modem 310 and provide the filtered transmission signal TX1 to the mixer 326. In embodiments, the internal impedance of the baseband filter 324 may be dynamically varied. The internal impedance of the baseband filter 324 may be varied based on the output power of the PA 328. For example, the output impedance of the baseband filter 324 may have a first value, when the output power of the PA 328 is below a threshold. The output impedance of the baseband filter 324 may have a second value smaller than the first value, when the output power of the PA 328 exceeds the threshold. The baseband filter 324 may include the analog filter 110 of FIG. 1. The internal impedance of the baseband filter 324 may be varied based on the level of the supply voltage VCC. When the supply voltage VCC changes from a first level to a second level lower than the first level, the internal impedance of the baseband filter 324 may change from the second value to the first value.

The mixer 326 may perform frequency up-conversion of the transmission signal TX1 from a baseband frequency to a high-frequency band (e.g., RF band) using the oscillation signal OS provided by the local oscillator LO. The frequency up-converted transmission signal TX2 may be provided to the DA 327. The DA 327 may primarily power amplify (or perform a first power amplification of) a transmission signal TX2 and provide an RF input signal RF_IN to PA 328.

The PA 328 may receive a supply voltage VCC, e.g., a dynamically varying output voltage, from the power modulator 340, and may generate an RF output signal RF_OUT by secondarily amplifying (or performing a second power amplification of) the power of the RF input signal RF_IN based on the received supply voltage VCC. And the PA 328 may provide the generated RF output signal RF_OUT to the duplexer 330.

The mixer 326 may include a plurality of mixer circuits, the DA 327 may include a plurality of DA circuits, and/or the PA 328 may include a plurality of PA circuits. One of the plurality of mixer circuits, one of the plurality of DA circuits, and/or one of the plurality of PA circuits are connected to the TX path, and, based on the control signal CON3, the remaining mixer circuits, the remaining DA circuits, and the remaining PA circuits may or may not be connected to the TX path. In embodiments, at least one of the remaining mixer circuits which is not connected to the TX path may be connected to the TX path based on the output power of the PA 328, the output impedance of the baseband filter 324, and/or the level of the supply voltage VCC. In embodiments, at least one of the remaining DA circuits not connected to the TX path may be connected to the TX path based on the output power of the PA 328, the output impedance of the baseband filter 324, and/or the level of the supply voltage VCC. In embodiments, at least one of the remaining PA circuits not connected to the TX path may be connected to the TX path based on the output power of the PA 328, the output impedance of the baseband filter 324, and/or the level of the supply voltage VCC.

For reference, the communication device 300 may transmit and receive signals through multiple frequency bands using carrier aggregation technology CA. Additionally, for performing this carrier aggregation, the communication device 300 may include a plurality of power amplifiers which amplify the power of a plurality of RF input signals, each corresponding to a plurality of carriers. However, in embodiments of the present disclosure, for convenience of explanation, an example in which there is only one PA 328 will be described.

The duplexer 330 may be connected to an antenna ANT to separate the transmission frequency and the reception frequency. Specifically, the duplexer 330 may separate the RF output signal RF_OUT provided from the PA 328 by frequency band and provide the separated RF output signal to a corresponding antenna ANT. Additionally, the duplexer 330 may provide an external signal received from the antenna ANT (e.g., RF_R) to the LNA 321.

For reference, the communication device 300 may be equipped with a switch structure capable of separating the transmission frequency and the reception frequency instead of the duplexer 330. Additionally, the communication device 300 may be equipped with a structure composed of a duplexer and a switch to separate the transmission frequency and the reception frequency.

The antenna ANT may transmit an RF output signal RF_OUT frequency-separated by the duplexer 330 to the outside (e.g., outside of the communication device 300) or provide an RF reception signal RF_R received from the outside to the duplexer 330. For example, the antenna ANT may include an array antenna.

The power modulator 340 may generate a modulated supply voltage VCC, the level of which dynamically changes based on a control signal CON1, and provide the supply voltage VCC as a power voltage to the PA 328.

The power modulator 340 may generate a plurality of voltages having different levels by using the battery voltage (which may be referred to as the supply voltage), and may provide one of these voltages to the PA 328 as the supply voltage VCC based on the control signal CON1. That is, the power modulator 340 may select the voltage corresponding to the control signal CON1 from among the plurality of voltages and provide the selected voltage to the PA 328 as the supply voltage VCC.

For reference, the configuration of the communication device 300 illustrated in FIG. 3 is also merely an example, and is not limited thereto, and may be configured in various ways depending on the communication protocol or communication method.

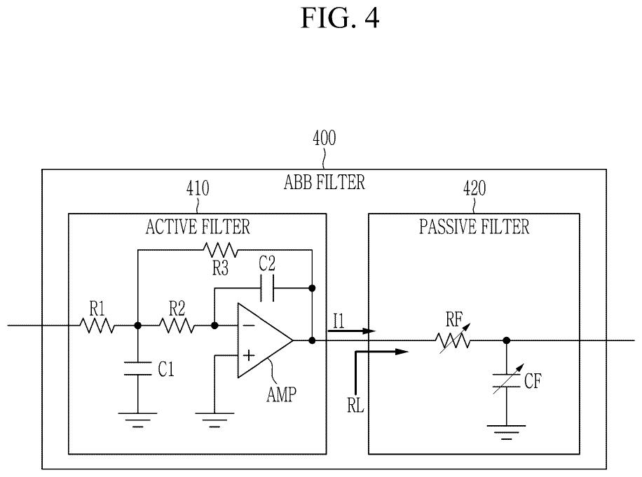

FIG. 4 is a schematic diagram of an equivalent circuit of an analog filter according to embodiments.

Referring to FIG. 4, the analog filter 400 (e.g., an ABB) may include an active filter 410 and/or a passive filter 420. According to embodiments, the analog filter 400 may also be referred to herein as an ABB filter 400 and/or a baseband filter 400. The active filter 410 may include passive components R1, R2, R3, C1, C2 and/or a baseband VGA AMP. The active filter 410 may include a low pass filter LPF structure. The output terminal of the baseband VGA AMP may be connected to the passive filter 420. The passive filter 420 may have a low-pass filter structure including at least one variable resistor RF and/or at least one variable capacitor CF. The resistance value of at least one variable resistor RF may be changed by the control signal CON2. The capacitance value of at least one variable capacitor CF may be changed by the control signal CON2. According to embodiments, for example, the resistance value of the at least one variable resistor RF and the capacitance value of the at least one variable capacitor CF may be changed together (e.g., simultaneously or contemporaneously) using the control signal CON2 (e.g., the same control signal CON2 or similar control signals CON2). For substantially the same bandwidth performance, the cutoff frequency determined by at least one variable resistor RF and/or at least one variable capacitor CF, whose resistance and capacitance values are changed by the control signal CON2, may be substantially the same as the cutoff frequency determined by the resistance value(s) of the at least one variable resistor RF and/or the capacitance value(s) of the at least one variable capacitor CF before the control signal CON2 was changed. That is, the R*C value of the passive filter 420 is maintained constant (or nearly constant), and the R value and C value may be changed.

In embodiments, the resistance value of the variable resistor RF may be increased by the control signal CON2. For example, in a region where the output power of the transmitter 100 in FIG. 1 is relatively low, the resistance value of the variable resistor RF may be increased by the control signal CON2. As illustrated in FIG. 2, Region 2 during which the variable resistor RF has a second resistance value (may also be referred to herein as a first period), which is greater than the first resistance value, may be longer than Region 1 during which the variable resistor RF has the first resistance value (may also be referred to herein as a second period). According to embodiments, the first period may refer to a duration of time in which the transmitter 100 is configured to output a signal having a lower output power (e.g., an output power below an output power threshold). According to embodiments, the second period may refer to a duration of time in which the transmitter 100 is configured to output a signal having a higher output power (e.g., an output power above the output power threshold). According to embodiments, the length of the first period being longer than the second period may refer to a usage frequency (e.g., usage rate) of the transmitter 100 at lower output power being higher than a usage frequency (e.g., usage rate) of the transmitter 100 at higher output power. Accordingly, with respect to a total usage duration of the transmitter 100, the first period may be longer than the second period. The impedance RL, as seen from the output terminal of the baseband VGA AMP toward the input terminal of the passive filter 420, may depend on the resistance value of the variable resistor RF in the passive filter 420. That is, in a region where the output power of the transmitter 100 is relatively low, the output impedance RL of the baseband VGA AMP may increase. For example, if the output power of the transmitter 100 is below a threshold, the output impedance RL of the baseband VGA AMP may increase. The gain of the baseband VGA AMP may be related to the output impedance RL of the baseband VGA AMP and the output current of the baseband VGA AMP. For example, if the output impedance RL of the baseband VGA AMP increases, the gain of the baseband VGA AMP may increase. As the output current I1 of the baseband VGA AMP increases, the gain of the baseband VGA AMP may increase. In embodiments, for substantially the same gain of the baseband VGA AMP, the output impedance RL of the baseband VGA AMP may be increased, and the output current I1 of the baseband VGA AMP may be decreased. Since the output current I1 of the baseband VGA AMP is reduced, the consumption current of the analog filter 400 may be reduced.

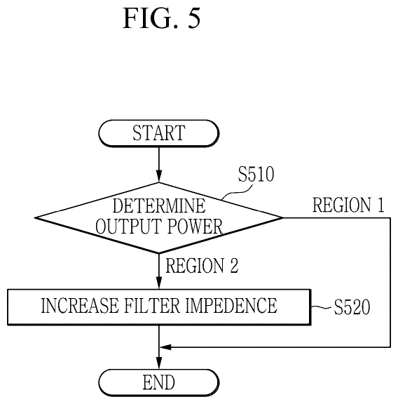

FIG. 5 is a flowchart of an operation method of a communication device according to embodiments.

Referring to FIGS. 3 to 5, the controller 314 may determine the output power of the PA 328 at operation S510. The controller 314 may determine the output power of the PA 328 based on the output level of the RF output signal RF_OUT. In embodiments, the controller 314 may adjust the gain of the PA 328. The controller 314 may provide a control signal to the PA 328 to adjust the gain of the PA 328.

If the output power of the PA 328 is within the second region Region 2 (e.g., in response to determining the output power of the PA 328 is within the second region Region 2), the controller 314 may increase the impedance of the baseband filter 324 at operation S520. Specifically, the controller 314 may increase the impedance of a passive filter 420 within the baseband filter 400. For example, if the output power of the PA 328 is below a threshold, the controller 314 may increase the impedance of the passive filter 420. In embodiments, the controller 314 may control the impedance of the passive filter 420 based on the output power of the PA 328. The controller 314 may control the passive filter 420 to a first value when the output power of the PA 328 is at a first level, and may control the passive filter 420 to a second value greater than the first value when the output power of the PA 328 is at a second level lower than the first level. Alternatively, the controller 314 may control the impedance of the passive filter 420 to a second value when the output power of the PA 328 is at a first level, and may control the impedance of the passive filter 420 to the first value when the output power of the PA 328 is at a second level lower than the first level.

As a result, the output impedance RL of the active filter 410 of the baseband filter 400 may increase, and the output current I1 of the active filter 410 may be reduced. By reducing the output current I1 of the active filter 410, the current consumption of the baseband filter 400 may be reduced. According to embodiments, if the output power of the PA 328 is within the first region Region 1 (e.g., in response to determining the output power of the PA 328 is within the first region Region 1), the controller 314 may skip operation S520. According to embodiments, after performing operation S520 (and/or after performing one or more of operations S730, S1130 and/or S1520 discussed below) the communication device 300 may perform network communication with another device (e.g., a base station, a UE, etc.). For example, the communication device 300 may generate a first signal (e.g., using the controller 314), process the first signal to perform one or more among modulating, upconverting, filtering, amplifying and/or encrypting on the first signal (e.g., using the modem 310, the transceiver 320 and/or the PA 328), and transmit the processed first signal to the other device via the antenna ANT. Additionally or alternatively, the communication device 300 may receive a second signal from the other device via the antenna ANT (e.g., in response to the transmitted processed first signal), process the second signal to perform one or more among demodulating, downconverting, filtering, amplifying and/or decrypting on the second signal (e.g., using the modem 310 and/or the transceiver 320), and perform a further operation(s) based on the processed second signal. For example, the further operation(s) may include one or more of providing the processed second signal to a corresponding application executing on the communication device 300, storing the processed second signal, sending a response signal to the other device (e.g., based on a processing result of the corresponding application executing on the communication device 300), etc.

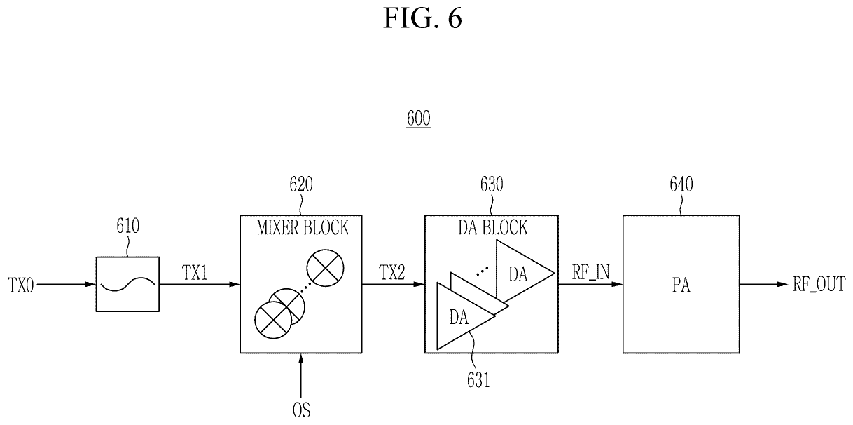

FIG. 6 is a block diagram illustrating a transmitter according to embodiments.

Referring to FIG. 6, the transmitter 600 may include a baseband filter 610, a mixer block 620, a DA block 630, and/or a PA 640. In embodiments, the PA 640 may be located external to the transmitter 600.

The baseband filter 610 may filter the baseband signal TX0 and provide the filtered transmission signal TX1 to the mixer block 620.

The mixer block 620 may receive a transmission signal TX1 and an oscillation signal OS, and may up-convert the frequency of the transmission signal TX1. The mixer block 620 may include a plurality of mixer circuits 621. At least one of the plurality of mixer circuits 621 may be connected to the baseband filter 610 and the DA block 630, and may receive a transmission signal TX1 and an oscillation signal OS, and perform frequency up-conversion to up-convert the frequency of the transmission signal TX1. If the output impedance of the active filter in the baseband filter 610 increases while the number of mixer circuits 621 remains unchanged, the ratio of the output impedance of the baseband filter 610 to the impedance of the mixer block 620 changes, which may result in a decrease in the gain between the baseband filter 610 and the mixer block 620. In embodiments, the number of mixer circuits connected to the baseband filter 610 and the DA block 630 among the plurality of mixer circuits 621 may be changed. For example, the output impedance of the active filter of the baseband filter 610 may increase, and the number of mixer circuits connected to the baseband filter 610 and the DA block 630 among the plurality of mixer circuits 621 may decrease. In embodiments, the number of mixer circuits performing frequency up-conversion among the plurality of mixer circuits 621 may be changed. For example, the output impedance of the active filter of the baseband filter 610 may increase, and the number of mixer circuits performing frequency up-conversion among the plurality of mixer circuits 621 may be reduced. The gain between the baseband filter 610 and the mixer block 620 may be maintained. Region2 during which the number of mixer circuits performing frequency up-conversion is a second number, which is less than a first number, may be longer than Region 1 during which the number of mixer circuits performing frequency up-conversion is the first number.

The DA block 630 may receive a frequency up-converted transmission signal TX2 from the mixer block 620, amplify the transmission signal TX2, and provide an RF input signal RF_IN to the PA 640. The DA block 630 may include a plurality of DA circuits 631. At least one of the plurality of DA circuits 631 may be connected to the mixer block 620 and the PA 640, and may amplify the transmit signal TX2 and generate an RF input signal RF_IN. In embodiments, the number of DA circuits connected to the mixer block 620 among the plurality of DA circuits 631 may be changed to achieve impedance matching with the mixer block 620. For example, the number of mixer circuits connected to the baseband filter 610 and the DA block 630 among the plurality of mixer circuits 621 may be reduced, and the number of DA circuits connected to the mixer block 620 among the plurality of DA circuits 631 may be reduced. In embodiments, the number of mixer circuits performing frequency up-conversion among the plurality of mixer circuits 621 may be changed, and the number of DA circuits 631 amplifying the transmission signal TX2 among the plurality of DA circuits 631 may be changed.

In embodiments, at least one of the plurality of DA circuits 631 may be connected to the PA 640. Based on the output power of the transmitter 600, some of the plurality of DA circuits 631 may be connected to the PA 640 and others may be turned off. For example, as the output power of the transmitter 600 increases, the number of DA circuits 631 connected to the PA 640 may increase, and the number of DA circuits 631 which are turned off may decrease. When the output power of the transmitter 600 decreases, the number of DA circuits 631 connected to the PA 640 may decrease, and the number of DA circuits 631 which are turned off may increase. When the output power of the transmitter 600 decreases below a threshold, some of the DA circuits 631 connected to the PA 640 may not be turned off but may be connected to the AC ground. Since the sizes of identically (or similarly) designed DA circuits 631 are substantially different from each other, when the DA circuit 631 is turned off, the impedance matching characteristics between the mixer blocks 620 may not change linearly. By connecting the output terminal of the DA circuit 631 to AC ground without turning off the DA circuit 631, the impedance matching characteristic between the DA block 630 and the mixer block 620 may be linearly changed. In embodiments, the output power of the transmitter 600 may be reduced, the output impedance of the active filter of the baseband filter 610 may be increased, and the DA circuit 631 connected to AC ground may be reconnected to the PA 640. If the output impedance of the active filter in the baseband filter 610 increases while the number of mixer circuits 621 remains unchanged, the ratio of the output impedance of the baseband filter 610 to the impedance of the mixer block 620 changes, which may result in a reduction in the gain between the baseband filter 610 and the mixer block 620. In this case, the output current of the DA block 630 may be increased by reconnecting the DA circuit 631 connected to the AC ground to the PA 640. If the output current of the DA block 630 increases, the magnitude or input power of the RF input signal RF_IN at the PA 640 also increases (where the magnitude or input power of the RF input signal RF_IN may be calculated based on the output current of the DA block 630 or the square of the output current), thereby reducing the influence of the decreased gain caused by changes in the output impedance of the active filter in the baseband filter 610.

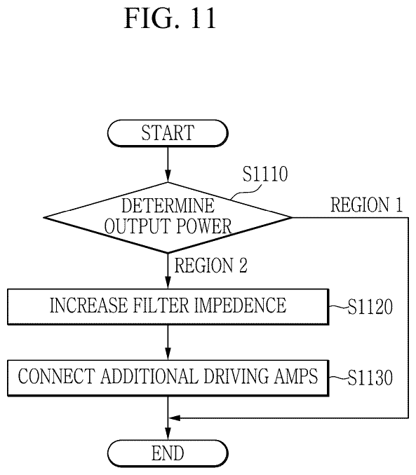

In embodiments, the plurality of DA circuits 631 may include a binary group and a unary group. DA circuits in the binary group may output power with binary weights. For example, the four DA circuits in the binary group may have output powers in ratios of 8, 4, 2, and 1, respectively. The DA circuits of the unary Group may output the same power (or similar power). The four DA circuits of the unary group may have output power in the ratio of 1, 1, 1, 1 respectively. If the output power of the transmitter 600 decreases below a certain threshold, among some DA circuits 631 connected to the PA 640, the DA circuits 631 which are connected to the AC ground may include at least one DA circuit of the unary group. In this regard, reference is made to FIGS. 11 to 13 as described below.

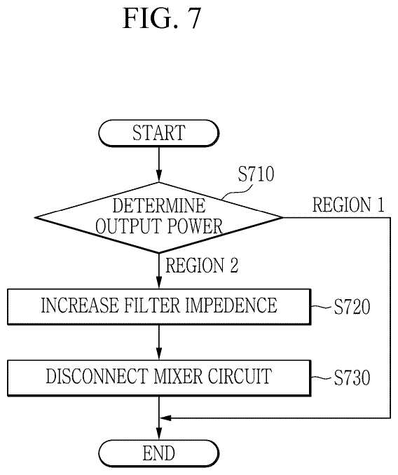

FIG. 7 is a flowchart of an operation method of a communication device according to embodiments.

Referring to FIGS. 3, 6, and 7, the controller 314 may determine the output power of the PA 328 at operation S710. The controller 314 may determine the output power of the PA 328 based on the output level of the RF output signal RF_OUT. In embodiments, the controller 314 may adjust the gain of the PA 328. The controller 314 may provide a control signal to the PA 328 to adjust the gain of the PA 328.

If the output power of the PA 328 is within Region 2 (e.g., in response to determining the output power of the PA 328 is within Region 2), the controller 314 may increase the impedance of the baseband filter 324 at operation S720. As a result, the output impedance RL of the active filter 410 of the baseband filter 400 may increase, and the output current I1 of the active filter 410 may be reduced. By reducing the output current I1 of the active filter 410, the current consumption of the baseband filter 400 may be reduced.

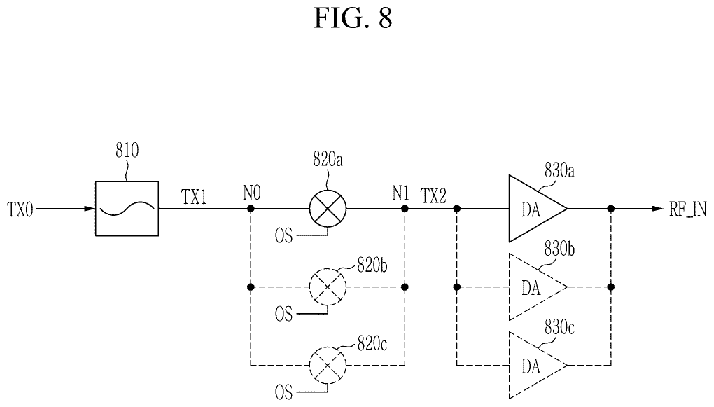

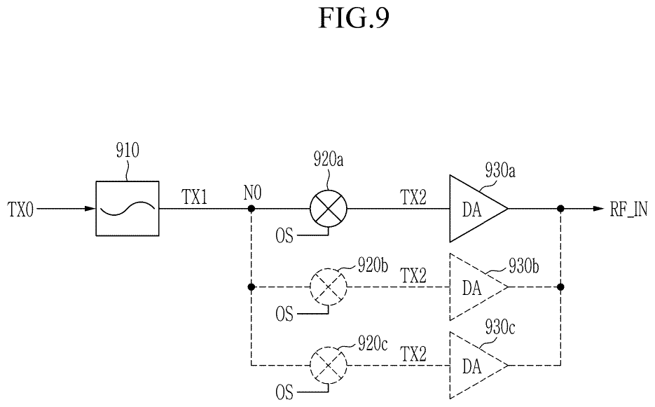

If the output power of the PA 328 is within Region 2 (e.g., in response to determining the output power of the PA 328 is within Region 2), the controller 314 may disconnect the connection between the mixer circuit 621 and the baseband filter 610 at operation S730. The controller 314 may maintain the gain between the baseband filter 610 and the mixer block 620 by reducing the number of mixer circuits 621 connected to the baseband filter 610 in response to a change in the impedance of the baseband filter 610. In this regard, a description will be provided with reference to FIGS. 8 and 9. According to embodiments, if the output power of the PA 328 is within Region 1 (e.g., in response to determining the output power of the PA 328 is within Region 1), the controller 314 may skip operations S720 and S730.

FIGS. 8 and 9 are block diagrams showing examples of transmitters controlled by the method of FIG. 7.

Referring to FIG. 8, a baseband filter 810 may filter a baseband signal TX0 and output a filtered transmission signal TX1.

Mixer circuits 820a, 820b, 820c may be connected (e.g., connected in parallel) between node N0 and node N1. The mixer circuits 820a, 820b, 820c may receive a transmission signal TX1 and an oscillation signal OS, and output a transmission signal TX2. At operation S730, the connection between the mixer circuit 820b, 820c and the baseband filter 810 may be disconnected.

The DA circuits 830a, 830b, 830c may receive a transmission signal TX2 and output an RF input signal RF_IN. The DA circuits 830b, 830c may be turned off corresponding to the disconnected mixer circuits 820b, 820c. Specifically, the DA circuits 830b, 830c may be turned off for impedance matching with the disconnected mixer circuits 820b, 820c. For example, a number of DA circuits 830b, 830c corresponding to (or equal to) the number of disconnected mixer circuits 820b, 820c may be turned off. Although the DA circuits 830b, 830c are described as being turned off above, at least some of the DA circuits 830b, 830c may be AC grounded.

Referring to FIG. 9, a baseband filter 910 may filter a baseband signal TX0 and output a filtered transmission signal TX1.

Mixer circuits 920a, 920b, 920c may be connected between a node N0 and a corresponding DA circuit among DA circuits 930a, 930b, 930c. For example, the mixer circuits 920a, 920b, 920c and the DA circuits 930a, 930b, 930c may be connected one-to-one. The mixer circuits 920a, 920b, 920c may receive a transmission signal TX1 and an oscillation signal OS and output a transmission signal TX2. At operation S730, the connection between the mixer circuit 920b, 920c and the baseband filter 910 may be disconnected.

The DA circuits 930a, 930b, 930c may receive a transmission signal TX2 and output an RF input signal RF_IN. The DA circuits 930b, 930c may be turned off corresponding to the disconnected mixer circuits 920b, 920c. Specifically, the DA circuits 930b, 930c may be turned off for impedance matching with the disconnected mixer circuits 920b, 920c. For example, a number of the DA circuits 930b, 930c corresponding to (or equal to) the number of disconnected mixer circuits 920b, 920c may be turned off. Although the DA circuits 930b, 930c are described as being turned off above, at least some of the DA circuits 930b, 930c may be AC grounded.

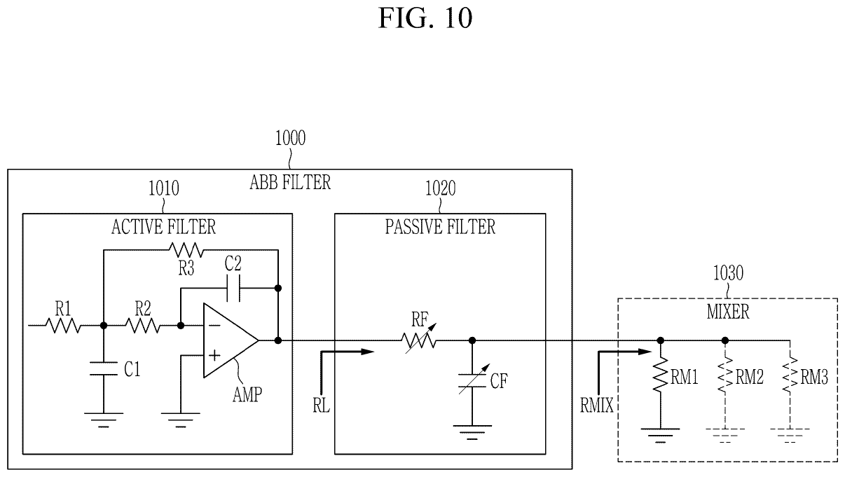

FIG. 10 is a block diagram showing an analog filter of the transmitter of FIGS. 8 and 9.

As illustrated in FIG. 10, the baseband filter 1000 includes an active filter 1010 and/or a passive filter 1020, and the resistance RF of the passive filter 1020 may increase, the capacitance CF may decrease, and the output impedance RL of the active filter 1010 may increase. Due to the disconnection of the mixer circuits 820b, 820c or the mixer circuits 920b, 920c, the impedance RMIX as seen by the baseband filter 1000 toward a mixer block 1030 may increase from a parallel impedance composed of the impedances RM1 of the mixer circuit 820a or 920a, RM2 of the mixer circuit 820b or 920b, and RM3 of the mixer circuit 820c or 920c, to the impedance RM1 of the mixer circuit 820a or 920a. Accordingly, even if the impedance of the baseband filter 1000 increases, the gain according to the ratio of the impedance between the baseband filter 1000 and the mixer block 1030 may be maintained.

FIG. 11 is a flowchart of an operation method of a communication device according to embodiments.

Referring to FIGS. 3, 6, and 11, the controller 314 may determine the output power of the PA 328 at operation S1110. The controller 314 may determine the output power of the PA 328 based on the output level of the RF output signal RF_OUT. In embodiments, the controller 314 may adjust the gain of the PA 328. The controller 314 may provide a control signal to the PA 328 to adjust the gain of the PA 328.

If the output power of the PA 328 is within Region 2 (e.g., in response to determining the output power of the PA 328 is within Region 2), the controller 314 increases the impedance of the baseband filter 324 at operation S1120. As a result, the output impedance RL of the active filter 410 of the baseband filter 400 may increase, and the output current I1 of the active filter 410 may be reduced. By reducing the output current I1 of the active filter 410, the current consumption of the baseband filter 400 may be reduced.

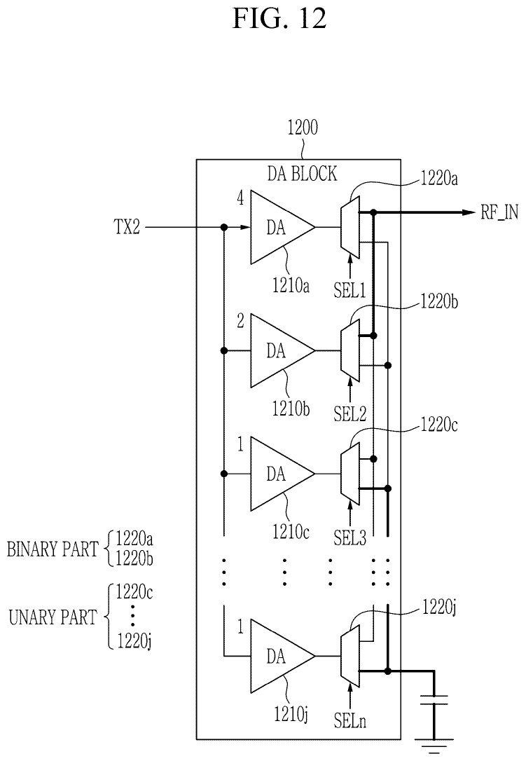

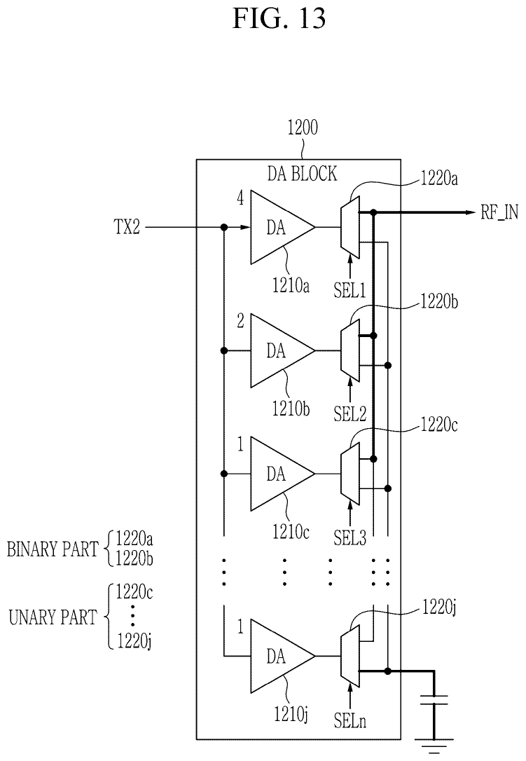

If the output power of PA 328 is within Region 2 (e.g., in response to determining the output power of the PA 328 is within Region 2), the controller 314 may connect an additional DA circuit to the PA at operation S1130. The controller 314 may compensate for the reduced gain between the baseband filter 610 and the mixer block 620 by additionally operating the DA circuit 631 in response to a change in impedance of the baseband filter 610. In relation to this, it is described together with reference to FIGS. 12 and 13. According to embodiments, if the output power of PA 328 is within Region 1 (e.g., in response to determining the output power of the PA 328 is within Region 1), the controller 314 may skip operations S1120 and S1130.

FIGS. 12 and 13 are block diagrams showing examples of driving amplifier blocks controlled by the method of FIG. 11.

Referring to FIG. 6 and FIG. 12, the DA block 1200 may receive a transmission signal TX2 and output an RF input signal RF_IN. The DA block 1200 may include a plurality of DA circuits 1210a, 1210b, 1210c, . . . , 1210j and a plurality of multiplexer circuits 1220a, 1220b, 1220c, . . . , 1220j.

The plurality of DA circuits 1210a, 1210b, 1210c, . . . , 1210j may be connected to (e.g., respectively connected to) the plurality of multiplexer circuits 1220a, 1220b, 1220c, . . . , 1220j. For example, the DA circuit 1210a may be connected to a corresponding multiplexer circuit 1220a. The plurality of DA circuits 1210a, 1210b, 1210c, . . . , 1210j may be included in a binary group and a unary group, respectively. For example, the DA circuits 1210a, 1210b may be included in the binary group, and the DA circuits 1210c, . . . , 1210j may be included in the unary group. The output power of the DA circuits 1210a, 1210b included in the binary group may have binary weights. For example, the output power of the DA circuit 1210a may be four times the output power of the DA circuit 1210c, and the output power of the DA circuit 1210b may be twice the output power of the DA circuit 1210c. The output power of the DA circuits 1210c, . . . , 1210j included in the unary group may be substantially identical to each other.

The plurality of multiplexer circuits 1220a, 1220b, 1220c, . . . , 1220j may connect output terminals of the plurality of DA circuits 1210a, 1210b, 1210c, . . . , 1210j to the PA 640 or to AC ground based on a plurality of selection signals SEL1, SEL2, SEL3, . . . , SELn. In embodiments, to reduce the output current consumption of the DA block 1200, the output terminal of at least one DA circuit may be connected to AC ground. For example, by selection signals SEL3, . . . , SELn, the output terminals of the DA circuits 1210c, . . . , 1210j in the unary group may be connected to AC ground. By connecting the output terminals of the DA circuits 1210c, . . . , 1210j to AC ground without turning off the DA circuits 1210c, . . . , 1210j, the impedance matching characteristics between the DA block 1200 and the mixer block may be linearly changed. According to embodiments, the plurality of selection signals SEL1, SEL2, SEL3, . . . , SELn may be generated and provided by the controller 314.

Referring to FIG. 13, if the output power of the PA 328 is within Region 2 (e.g., in response to determining the output power of the PA 328 is within Region 2), at least some of the DA circuits 1210c, . . . , 1210j (e.g., the DA circuit 1210c) connected to the AC ground may be reconnected to the PA 640. If the output impedance of the active filter in the baseband filter 610 increases while the number of mixer circuits 621 remains unchanged, the ratio of the output impedance of the baseband filter 610 to the impedance of the mixer block 620 changes, which may result in a decrease in the gain between the baseband filter 610 and the mixer block 620. In this case, by reconnecting the DA circuit 1210c (previously connected to the AC ground) to the PA 640, the output current of the DA block 1200 is increased. As a result, the magnitude or input power of the input signal RF_IN is raised, thereby reducing the influence of the decreased gain caused by the change in the output impedance of the active filter in the baseband filter 610.

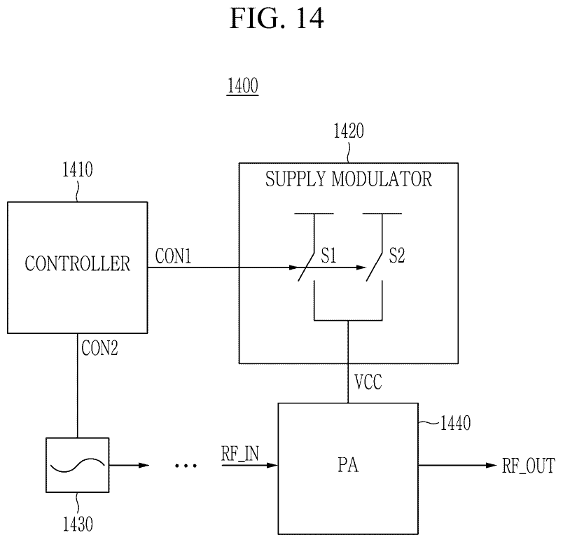

FIG. 14 is a block diagram illustrating a portion of a communication device according to embodiments.

Referring to FIG. 14, a communication device 1400 may include a controller 1410, a power modulator 1420, a baseband filter 1430, and/or a PA 1440. The controller 1410 may determine the output power of the PA 1440. The controller 1410 may change the level of the power supply voltage VCC provided to the PA 1440 based on the output power of the PA 1440. For example, the controller 1410 may provide a relatively low level voltage V1 to the PA 1440 as a power supply voltage VCC when the output power of the PA 1440 is relatively low. The controller 1410 may provide a relatively high level voltage V2 to the PA 1440 as a power supply voltage VCC when the output power of the PA 1440 is relatively high. The controller 1410 may provide a control signal CON1 to the power modulator 1420 which controls switches S1, S2 connected to voltages V1, V2. The PA 1440 may receive power voltage VCC, amplify RF input signal RF_IN, and output RF output signal RF_OUT.

The controller 1410 may provide a control signal CON2 to the baseband filter 1430 to change the impedance of the baseband filter 1430 based on the output power of the PA 1440.

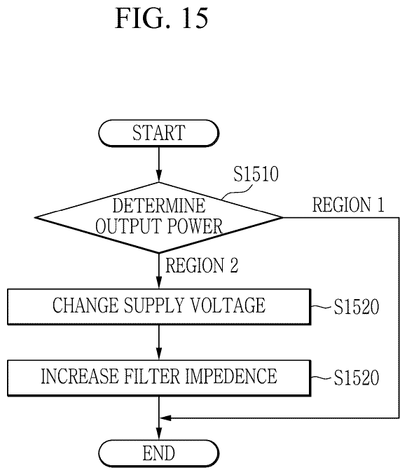

FIG. 15 is a flowchart of an operation method of a communication device according to embodiments.

Referring to FIGS. 14 and 15, the controller 1410 may determine the output power of the PA 1440 at operation S1510. The controller 1410 may determine the output power of the PA 1440 based on the output level of the RF output signal RF_OUT.

If the output power of the PA 1440 is within Region 2 (e.g., in response to determining the output power of the PA 1440 is within Region 2), the controller 1410 may adjust the level of the power voltage VCC provided to the PA 1440 at operation S1520. The controller 1410 may provide a control signal CON1 which controls the level of the power voltage VCC provided to the PA 1440 to the power modulator 1420. For example, if the output power of the PA 1440 is within Region 2, the controller 1410 may change the level of the power voltage VCC provided to the PA 1440 to a relatively low level.

If the output power of the PA 1440 is within Region 2 (e.g., in response to determining the output power of the PA 1440 is within Region 2), the controller 1410 may increase the impedance of the baseband filter 324 at operation S1530. As a result, the output impedance RL of the active filter 410 of the baseband filter 400 may increase, and the output current I1 of the active filter 410 may be reduced. By reducing the output current I1 of the active filter 410, the current consumption of the baseband filter 400 may be reduced. According to embodiments, if the output power of the PA 1440 is within Region 1 (e.g., in response to determining the output power of the PA 1440 is within Region 1), the controller 1410 may skip operations S1520 and S1530

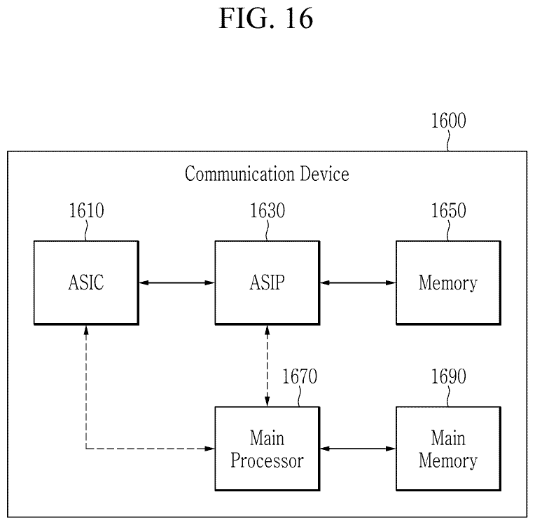

FIG. 16 is a block diagram illustrating a communication device according to embodiments.

Referring to FIG. 16, the communication device 1600 may include an ASIC Application Specific Integrated Circuit (ASIC) 1610, an Application Specific Instruction set Processor (ASIP) 1630, a memory 1650, a main processor 1670, and/or a main memory 1690. Two or more of the ASIC 1610, ASIP 1630 and/or main processor 1670 may communicate with each other. Additionally, at least two of the ASIC 1610, ASIP 1630, memory 1650, main processor 1670, and/or main memory 1690 may be embedded in one chip.

The ASIP 1630 is an integrated circuit customized for a specific purpose, may support a dedicated instruction set for a specific application, and may execute instructions included in the instruction set. The memory 1650 may communicate with the ASIP 1630 and, as a non-transitory storage device, may store a plurality of instructions executed by the ASIP 1630. For example, the memory 1650 may, by way of non-limiting example, include any type of memory accessible by the ASIP 1630, such as Random Access Memory (RAM), Read Only Memory (ROM), tape, magnetic disk, optical disk, volatile memory, non-volatile memory, or any combination thereof.

The main processor 1670 may control the communication device 1600 by executing multiple instructions. For example, the main processor 1670 may control the ASIC 1610 and/or the ASIP 1630, process data received over a wireless communications network, and/or process user input to the communications device 1600. The main memory 1690 may communicate with the main processor 1670 and, as a non-transitory storage device, may store a plurality of instructions executed by the main processor 1670. For example, the main memory 1690 may include any type of memory accessible by the main processor 1670, such as Random Access Memory (RAM), Read Only Memory (ROM), tape, magnetic disk, optical disk, volatile memory, non-volatile memory, or any combination thereof, by way of non-limiting example.

The transmitter according to the present disclosure described in FIGS. 1 to 15 may be included in all or part of the configuration of the communication device 1600 of FIG. 16. The method of operating the communication device according to the present disclosure described in FIGS. 1 to 15 may be performed by at least one of the components included in the communication device 1600 of FIG. 16. In embodiments, the operations of the controller 314 of FIGS. 5, 7, 11, and 15 may be implemented as a plurality of instructions stored in the memory 1650, and/or the ASIP 1630 may perform at least one of the operations of the method of operating the communication device by executing the plurality of instructions stored in the memory 1650. In embodiments, at least one of the operations of the method of operating the communication device may be performed by a hardware block designed through logic synthesis or the like, and such a hardware block may be included in the ASIC 1610. In embodiments, at least one of the operations of the method of operating the communication device may be implemented as a plurality of instructions stored in the main memory 1690, and the main processor 1670 may perform at least one of the operations of the method of operating the communication device by executing the plurality of instructions stored in the main memory 1690.

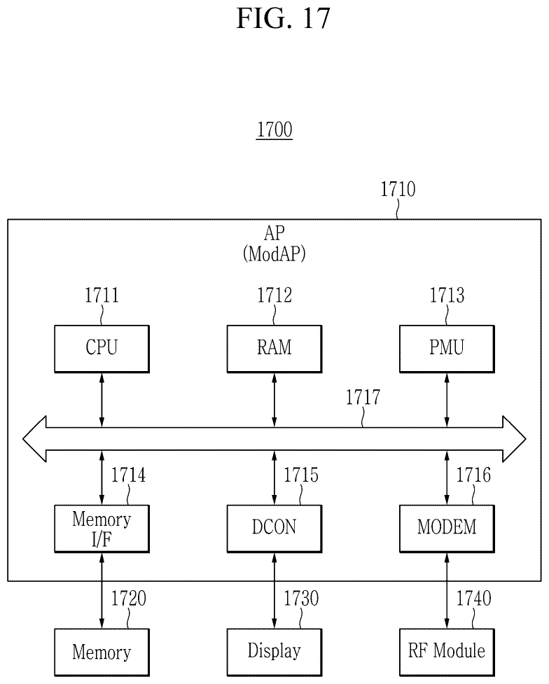

FIG. 17 is a block diagram illustrating a mobile terminal to which a communication device according to embodiments is applied.

Referring to FIG. 17, a mobile terminal 1700 may include an application processor 1710; hereinafter referred to as AP, a memory 1720, a display 1730, and/or an RF module 1740. In addition, the mobile terminal 1700 may further include various components such as a lens, a sensor, an audio module, etc.

The AP 1710 may be implemented as a system on chip SoC and may include a central processing unit CPU 1711, a RAM 1712, a power management unit PMU 1713, a memory interface 1714, a display controller 1715, a modem 1716, and/or a bus 1717. The AP 1710 may also include various other IPs. The AP 1710 may be referred to as ModAP as it has the function of a modem chip integrated into the AP 1710.

The CPU 1711 may control the overall operation of the AP 1710 and the mobile terminal 1700. The CPU 1711 may control the operation of each component of the AP 1710. Additionally, the CPU 1711 may be implemented as multi-core. Multi-core is a computing component which has two or more independent cores.

A RAM 1712 may temporarily store programs, data, or instructions. For example, programs and/or data stored in memory 1720 may be temporarily stored in the RAM 1712 according to the control or booting code of CPU 1711. The RAM 1712 may be implemented as dynamic RAM (DRAM) or static RAM (SRAM).

The PMU 1713 may manage the power of each component of the AP 1710. The PMU 1713 may also judge the operating status of each component of the AP 1710 and control operation of the AP 1710.

The memory interface 1714 may control the overall operation of the memory 1720 and may control data exchange between each component of the AP 1710 and the memory 1720. The memory interface 1714 may write data to or read data from the memory 1720 at the request of the CPU 1711.

The display controller 1715 may transmit image data to be displayed on the display 1730 to the display 1730. The display 1730 may be implemented as a flat display such as a liquid crystal display LCD, an organic light emitting diode OLED, a flexible display, etc.

The modem 1716 may modulate data to be transmitted for wireless communication to suit the wireless environment and recover received data. The modem 1716 may perform digital communication with the RF module 1740.

For reference, the modem 1716 may implement the modem 310 described above with reference to FIGS. 3, 5, 7, 11, and 15.

The RF module 1740 may convert a higher frequency signal received through an antenna into a lower frequency signal and transmit the converted lower frequency signal to a modem 1716. Additionally, the RF module 1740 may convert a lower-frequency signal received from the modem 1716 into a higher-frequency signal and transmit the converted higher-frequency signal to the outside of the mobile terminal 1700 through an antenna. Additionally, the RF module 1740 may amplify or filter the signal.

For reference, the transmitter described above with reference to FIGS. 1 to 15 may be implemented in such RF modules 1740.

For this reason, in a mobile terminal 1700, wideband communication may be possible while reducing power consumption for communication.

In embodiments, any of the components or combinations of two or more components described with reference to FIGS. 1 through 17 may be implemented in digital circuits, programmable or non-programmable logic devices or arrays, application-specific integrated circuits (ASICs), or the like.

Conventional devices and methods for transmitting wireless signals only reduce power consumption in scenarios in which the wireless signal is transmitted at higher power (e.g., at a power level above a power threshold). However, wireless signals are transmitted at lower power (e.g., at power levels below the power threshold) at a higher rate than wireless signals are transmitted at the higher power. Accordingly, the conventional devices and methods suffer from excessive power consumption. This excessive power consumption is particularly disadvantageous in use cases involving wireless signals transmitted by mobile devices reliant on limited battery power.

However, according to embodiments, improved devices and methods are provided for transmitting wireless signals. For example, the improved devices and methods may involve increasing an impedance of a passive filter to reduce an output current of an active filter in scenarios in which wireless signals are transmitted at lower power (e.g., at power levels below a power threshold), thereby reducing power consumption in the active filter. According to some examples, an output impedance of the active filter is increased while a transconductance of the active filter is decreased, thereby maintaining linear performance while reducing the power consumption. Therefore, the improved devices and methods overcome the deficiencies of the conventional devices and methods to at least reduce resource consumption.

According to embodiments, operations described herein as being performed by the transmitter 100, the analog filter 110, the TX block 120, the active filter 111, the passive filter 112, the communication device 300, the modem 310, the transceiver 320, the switch/duplexer 330, the power modulator 340, the analog/digital converter ADC 311, the digital/analog converter DAC 312, the switch controller 314, the low noise amplifier LNA 321, the mixer 322, the baseband filter 323, the local oscillator LO, the baseband filter 324, the TX block 325, the mixer 326, the DA 327, the PA 328, the analog filter 400, the active filter 410, the passive filter 420, the transmitter 600, the baseband filter 610, the mixer block 620, the DA block 630, the PA 640, the baseband filter 810, each of the mixer circuits 820a, 820b, 820c, each of the DA circuits 830a, 830b, 830c, the baseband filter 910, each of the mixer circuits 920a, 920b, 920c, each of the DA circuits 930a, 930b, 930c, the baseband filter 1000, the active filter 1010, the passive filter 1020, the mixer block 1030, the DA block 1200, each among the plurality of DA circuits 1210a, 1210b, 1210c, . . . , 1210j, each among the plurality of multiplexer circuits 1220a, 1220b, 1220c, . . . , 1220j, the communication device 1600, the ASIC 1610, the ASIP 1630, the main processor 1670, the mobile terminal 1700, the application processor 1710, the RF module 1740, the central processing unit CPU 1711, the power management unit PMU 1713, the memory interface 1714, the display controller 1715 and/or the modem 1716 may be performed by processing circuitry. The term ‘processing circuitry,’ as used in the present disclosure, may refer to, for example, hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), a digital signal processor, a microcomputer, a field programmable gate array (FPGA), a System-on-Chip (SoC), a programmable logic unit, a microprocessor, application-specific integrated circuit (ASIC), etc.

The various operations of methods described above may be performed by any suitable device capable of performing the operations, such as the processing circuitry discussed above. For example, as discussed above, the operations of methods described above may be performed by various hardware and/or software implemented in some form of hardware (e.g., processor, ASIC, etc.).

The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or operations of a method or algorithm, and/or functions, described in connection with embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium (e.g., the memory 1650, the main memory 1690, the memory 1720, the RAM 1712, etc.). A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

The term “outside” refers to a region that is beyond the outermost confines of a physical object. The term “inside’ indicates that at least a portion of a region is partially contained within a boundary formed by the object. The term “substantially’ is defined to be essentially conforming to the particular dimension, shape or other word that substantially modifies, such that the component need not be exact. As used herein the term “and/or” includes any and all combinations of one or more of the associated listed items.

Embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail herein. Although discussed in a particular manner, a function or operation specified in a specific block may be performed differently from the flow specified in a flowchart, flow diagram, etc. For example, functions or operations illustrated as being performed serially in two consecutive blocks may actually be performed concurrently, simultaneously, contemporaneously, or in some cases be performed in reverse order.

When one constituent element is described as being “coupled” or “connected” to another constituent element, it should be understood that one constituent element may be coupled or connected directly to another constituent element, and an intervening constituent element may also be present between the constituent elements. When one constituent element is described as being “coupled directly to” or “connected directly to” another constituent element, it should be understood that no intervening constituent element exists between the constituent elements.

Any of the arrows or lines that interconnect the components in the drawings may represent physical data paths, logical data paths, or both. A physical data path may comprise a data bus or a transmission line, for example. A logical data path may represent a communication or data message between software programs, software modules, subroutines, or other software constituents or components.

Although embodiments of the inventive concepts have been described in detail above, the scope of the inventive concepts are not limited thereto, and various modifications and improvements made by those skilled in the art using the basic concept of the inventive concepts defined in the following claims also fall within the scope of the inventive concepts.

What is claimed is:

1. An analog filter circuit comprising:
an active filter configured to filter a transmission signal, the active filter including an active element to which a power supply voltage is applied; and
a passive filter connected to an output terminal of the active filter, the passive filter including a passive element having a dynamically variable impedance.

2. The analog filter circuit of claim 1, wherein the passive element includes:
a variable resistor, a first end of the variable resistor being connected to the output terminal of the active filter; and
a variable capacitor connected to a second end of the variable resistor.

3. The analog filter circuit of claim 2, wherein
the variable resistor is configured to change a resistance value based on a control signal; and
the variable capacitor is configured to change a capacitance value based on the control signal.

4. The analog filter circuit of claim 2, wherein
a product of a resistance value of the variable resistor and a capacitance value of the variable capacitor is constant.

5. The analog filter circuit of claim 2, wherein
the variable resistor is configured to have a resistance value of
a first value during a first period, and
a second value during a second period,
the second value being greater than a first value, and the second period being longer than the first period.

6. The analog filter circuit of claim 1, wherein
the active filter and the passive filter each have a low-pass filter structure.

7. A transmitter comprising:
a baseband filter having a dynamically variable internal impedance, the baseband filter being configured to filter a baseband signal to obtain a first transmission signal;
a mixer configured to up-convert a frequency of the first transmission signal based on an oscillation signal to obtain a second transmission signal;
a driving amplifier configured to amplify the second transmission signal to generate a radio frequency (RF) input signal; and
a power amplifier configured to amplify the RF input signal to generate an RF output signal.

8. The transmitter of claim 7, wherein
the baseband filter is configured to have
a first internal impedance based on an output power of the transmitter being below a first threshold, and
a second internal impedance based on the output power of the transmitter being above the first threshold,
the first internal impedance being higher than the second internal impedance.

9. The transmitter of claim 8, wherein
the mixer includes a plurality of mixer circuits, the plurality of mixer circuits including a first subset of mixer circuits and a second subset of mixer circuits, the first subset of mixer circuits being configured to perform frequency up-conversion of the first transmission signal based on an output power of the transmitter being below a first threshold, the second subset of mixer circuits being configured to perform frequency up-conversion of the first transmission signal based on the output power of the transmitter being above the first threshold; and
a number of the first subset of mixer circuits is less than a number of the second subset of mixer circuits.

10. The transmitter of claim 8, wherein
the driving amplifier includes a plurality of driving amplifier circuits, the plurality of driving amplifier circuits including a first subset of driving amplifier circuits and a second subset of driving amplifier circuits, the first subset of driving amplifier circuits being configured to generate the RF input signal based on an output power of the transmitter being below a first threshold, the second subset of driving amplifier circuits being configured to generate the RF input signal based on the output power of the transmitter being above the first threshold; and
a number of the first subset of driving amplifier circuits is greater than a number of the second subset of driving amplifier circuits.

11. The transmitter of claim 10, wherein
each among the plurality of driving amplifier circuits is included in one among a binary group and a unary group; and
at least one driver amplifier circuit included in the unary group is configured to
connect to AC ground based on the output power of the transmitter being above the first threshold, and
generate the RF input signal based on the output power of the transmitter being below the first threshold.

12. The transmitter of claim 8, wherein
the transmitter is configured to have
a first output power above a first threshold during a first period, and
a second output power below the first threshold during a second period; and
the second period is longer than the first period.

13. The transmitter of claim 8, wherein
the power amplifier is configured to receive
a first level power voltage based on an output power of the transmitter being above a first threshold, and
a second level power voltage based on the output power of the transmitter being below the first threshold,
the second level power voltage being lower than the first level power voltage.

14. The transmitter of claim 8, wherein the baseband filter includes:
an active filter including an active element to which a power supply voltage is applied; and
a passive filter including a passive element having a dynamically variable impedance, the passive filter being connected to an output terminal of the active filter.

15. The transmitter of claim 14, wherein the passive element includes:
a variable resistor, a first end of the variable resistor being connected to the output terminal of the active filter; and
a variable capacitor connected to a second end of the variable resistor.

16. The transmitter of claim 15, wherein
the variable resistor is configured to change a resistance value based on a control signal; and
the variable capacitor is configured to change a capacitance value based on the control signal.

17. The transmitter of claim 15, wherein
a product of a resistance value of the variable resistor and a capacitance value of the variable capacitor is constant.

18. The transmitter of claim 15, wherein
the variable resistor is configured to have a resistance value of
a first value based on an output power of the transmitter being above a first threshold, and
a second value based on the output power of the transmitter being below the first threshold; and
the second value is greater than the first value.

19. A communication device comprising:
a power modulator configured to generate a power supply voltage of a first level or a second level, the second level being lower than the first level; and
a transmitter including
a baseband filter configured to filter a baseband signal to obtain a filtered baseband signal, the baseband filter having a variable internal impedance,
a mixer configured to up-convert a frequency of the filtered baseband signal to generate a first transmission signal,
a drive amplifier configured to amplify the first transmission signal to generate an RF input signal, and
a power amplifier configured to amplify the RF input signal using the power supply voltage to generate an RF output signal.

20. The communication device of claim 19, further comprising:
processing circuitry is configured to
control the baseband filter to change the variable internal impedance based on an output power of the RF output signal, and
control the power modulator to provide the power supply voltage.
